(19) United States
(12) Patent Application Publication
(10) Pub. No.: US 2024/0382999 A1
(43) Pub. Date: Nov. 21, 2024

(54) MASK ASSEMBLY AND METHOD FOR MANUFACTURING THE SAME

(71) Applicant: Samsung Display Co., Ltd., Yongin-si (KR)

(72) Inventors: MINSEOK KIM, Yongin-si (KR); BYUNG IK KONG, Yongin-si (KR); SEO YEON KIM, Yongin-si (KR); HONG-KYUN AHN, Yongin-si (KR)

(21) Appl. No.: 18/660,092

(22) Filed: May 9, 2024

(30) Foreign Application Priority Data
May 16, 2023 (KR) 10-2023-0063219

(51) Int. Cl. B05C 21/00

(52) U.S. Cl. CPC B05C 21/005

(57) ABSTRACT

Provided is a mask assembly and a method of manufacturing the same. The mask assembly according to one or more embodiments of the present disclosure may include a mask frame defining a first opening, an open mask above the mask frame, and defining second openings arranged in a first direction and a second direction crossing the first direction, unit masks above the open mask, and defining a unit opening, the unit opening having an area that is less than an area of each of the second openings in plan view, and cell masks above the unit masks, and defining cell openings, one of the cell openings have an area that is less than the area of the unit opening.

### CROSS-REFERENCE TO RELATED APPLICATIONS

The present application claims priority to, and the benefit of, Korean Patent Application No. 10-2023-0063219, filed on May 16, 2023, in the Korean Intellectual Property Office, the entire disclosure of which is incorporated herein by reference.

### BACKGROUND

### 1. Field

The present disclosure herein relates to a mask assembly for forming a common layer of a display panel, and a method of manufacturing the same.

### 2. Description of Related Art

The display panel includes a plurality of pixels. Each of the pixels includes a driving element, such as a transistor, and a display element, such as an organic light-emitting element. The display element may be formed by stacking electrodes and various functional layers on a substrate.

Functional layers constituting the display element are provided after being patterned by using a mask having/defining an open region defined to pass therethrough. In this case, the shapes of the patterned functional layers may be controlled according to the shape of the open region of the mask. Accordingly, to improve the deposition quality of the patterned functional layers, it is suitable to develop a mask assembly, in which the open region is processed with high precision, and a method and technology for manufacturing such a mask assembly.

### SUMMARY

The present disclosure provides a mask assembly for forming a common layer of a display panel having a large area.

In addition, the present disclosure also provides a method for manufacturing a mask assembly with improved quality.

One or more embodiments of the present disclosure provides a mask assembly including a mask frame defining a first opening, an open mask above the mask frame, and defining second openings arranged in a first direction and a second direction crossing the first direction, unit masks above the open mask, and defining a unit opening, the unit opening having an area that is less than an area of each of the second openings in plan view, and cell masks above the unit masks, and defining cell openings, one of the cell openings have an area that is less than the area of the unit opening.

The unit masks may include a first unit mask defining a first unit opening, and a second unit mask defining a second unit opening, wherein the first unit mask includes two first long side portions extending in the first direction, and spaced apart in the second direction, and two first short side portions extending in the second direction, and spaced apart in the first direction, the two first short side portions and the two first long side portions being connected to define the first unit opening, wherein the second unit mask includes two second short side portions extending in the first direction, and spaced apart in the second direction, and two second long side portions extending in the second direction, and spaced apart in the first direction, the two second short side portions and the two second long side portions being connected to define the second unit opening.

An area of the first unit opening may be substantially equal to an area of the second unit opening in plan view.

The first short side portions and the first long side portions may have a same first width in plan view, wherein the second short side portions and the second long side portions have a same second width in plan view, the second width being less than the first width.

The first unit mask and the second unit mask may be provided in plurality in the first direction, wherein the second unit mask is spaced apart from the first unit mask in the second direction.

A length of the first long side portions may be greater than a length of the second long side portions.

A length of the first short side portions may be greater than a length of the second short side portions.

A first thickness of the first unit mask may be greater than a second thickness of the second unit mask.

The first thickness may be about 100 μm to about 150 μm.

The open mask and the unit masks may include a same material.

The open mask and the unit masks may include stainless steel or an INVAR® alloy.

In one or more embodiments of the present disclosure, a mask assembly may include a mask frame defining a first opening, an open mask above the mask frame, and defining second openings arranged in a first direction and in a second direction crossing the first direction, unit masks above the open mask, and defining a unit openings respectively corresponding to the second openings, and a cell mask above the unit masks, and defining cell openings respectively corresponding to the unit openings.

The unit openings may have a smaller area than the second openings corresponding thereto, in plan view.

The unit masks may include a first unit mask defining a first unit opening, and a second unit mask defining a second unit opening, wherein the first and second unit masks are provided in plurality in the first direction, and are spaced apart in the second direction, wherein a width of the first unit opening in the first direction is greater than a width of the second unit opening in the first direction, and wherein a width of the first unit opening in the second direction is less than a width of the second unit opening in the second direction.

The first unit mask may be provided in two, and the second unit mask may be provided in six.

In one or more embodiments of the present disclosure, a method for manufacturing a mask assembly may include preparing a mask frame defining a first opening, coupling, to a top surface of the mask frame, an open mask defining second openings in a first direction and a second direction crossing the first direction, coupling, to a top surface of the open mask, unit masks defining unit openings respectively corresponding to two or more of the second openings, and coupling, to top surfaces of the unit masks, cell masks defining cell openings, wherein a number of the second openings decreases between the coupling of the unit masks and the coupling of the cell masks, and wherein, in plan view, a size of the second openings increases between the coupling of the unit masks and the coupling of the cell masks.

The unit masks may include a first unit mask defining a first unit opening, and a second unit mask defining a second unit opening, wherein the first unit mask and the second unit mask are spaced apart in the second direction, wherein a width of the first unit opening in the first direction is greater than a width of the second unit opening in the first direction, and wherein a width of the first unit opening in the second direction is less than a width of the second unit opening in the second direction.

A first thickness of the first unit mask may be greater than a second thickness of the second unit mask.

The open mask may include a first portion and a second portion spaced apart in the second direction and extending in the first direction, a third portion connecting one end of the first portion to one end of the second portion, a fourth portion connect another end of the first portion to another end of the second portion, fifth portions spaced apart in the second direction between the first portion and the second portion, and sixth portions spaced apart in the first direction between the third portion and the fourth portion, wherein the method further includes, prior to the coupling the cell masks, removing the fifth and sixth portions overlapping the unit opening in plan view.

The cell openings may be provided in plurality in each of the cell masks, wherein the cell openings defined in each of the cell masks are in the unit openings corresponding thereto in plan view.

### BRIEF DESCRIPTION OF DRAWINGS

The accompanying drawings are included to provide a further understanding of the present disclosure, and are incorporated in and constitute a part of this specification. The drawings illustrate embodiments of the present disclosure and, together with the description, serve to explain aspects of the present disclosure. In the drawings:

FIG. 1A is an exploded perspective view illustrating a mask assembly according to one or more embodiments of the present disclosure;

FIG. 1B is an exploded perspective view illustrating some components of the mask assembly according to one or more embodiments of the present disclosure;

FIG. 2A is a perspective view of some components of the mask assembly combined according to one or more embodiments of the present disclosure;

FIG. 2B is a perspective view of some components of the mask assembly combined according to one or more embodiments of the present disclosure;

FIG. 3 is a perspective view of some components of the mask assembly combined according to one or more embodiments of the present disclosure;

Each of FIGS. 4A and 4B is a plan view illustrating some components of the mask assembly according to one or more embodiments of the present disclosure;

FIG. 5 is a plan view illustrating some components of the mask assembly according to one or more embodiments of the present disclosure;

Each of FIGS. 6A and 6B is a cross-sectional view illustrating some components of the mask assembly according to one or more embodiments of the present disclosure;

FIG. 7 is a plan view of a display panel that may be manufactured by using the mask assembly according to one or more embodiments of the present disclosure;

FIG. 8 illustrates a cross-sectional configuration of any one pixel illustrated in FIG. 7;

FIG. 9 illustrates a cross section of the display panel adjacent to an edge of a display region in FIG. 7; and

FIGS. 10A to 10D schematically illustrate a manufacturing process of a mask assembly according to one or more embodiments of the present disclosure.

### DETAILED DESCRIPTION

In this specification, it will be understood that when an element (or region, layer, portion, etc.) is referred to as being “on”, “connected to” or “coupled to” another element, it can be directly on, connected or coupled to the other element, or intervening elements may be present.

Like reference numerals refer to like elements throughout. In addition, in the drawings, the thicknesses, ratios, and dimensions of elements are exaggerated for effective description of the technical contents. As used herein, the term “and/or” includes any and all combinations that the associated configurations can define.

It will be understood that, although the terms first, second, etc. may be used herein to describe various elements, these elements should not be limited by these terms. These terms are only used to distinguish one element from another element.

For example, a first element could be termed a second element without departing from the scope of the present invention. Similarly, the second element may also be referred to as the first element. The terms of a singular form include plural forms unless otherwise specified.

In addition, terms, such as “below”, “lower”, “above”, “upper” and the like, are used herein for ease of description to describe one element's relation to another element(s) as illustrated in the figures. The above terms are relative concepts and are described based on the directions indicated in the drawings.

It will be understood that the terms “include” and/or “have”, when used in this specification, specify the presence of stated features, integers, steps, operations, elements, components and/or groups thereof, but do not preclude the presence or addition of one or more other features, integers, steps, operations, elements, components, and/or groups thereof.

In the present application, being “directly located” may mean that there is no layer, film, region, plate, or the like added between a part, such as a layer, film, region, or plate and another part, such as a layer, film, region, or plate. For example, being “directly located” may mean that no additional member, such as an adhesive member is located between two layers or two members.

When one or more embodiments may be implemented differently, a specific process order may be performed differently from the described order. For example, two consecutively described processes may be performed substantially at the same time or performed in an order opposite to the described order.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to the drawings.

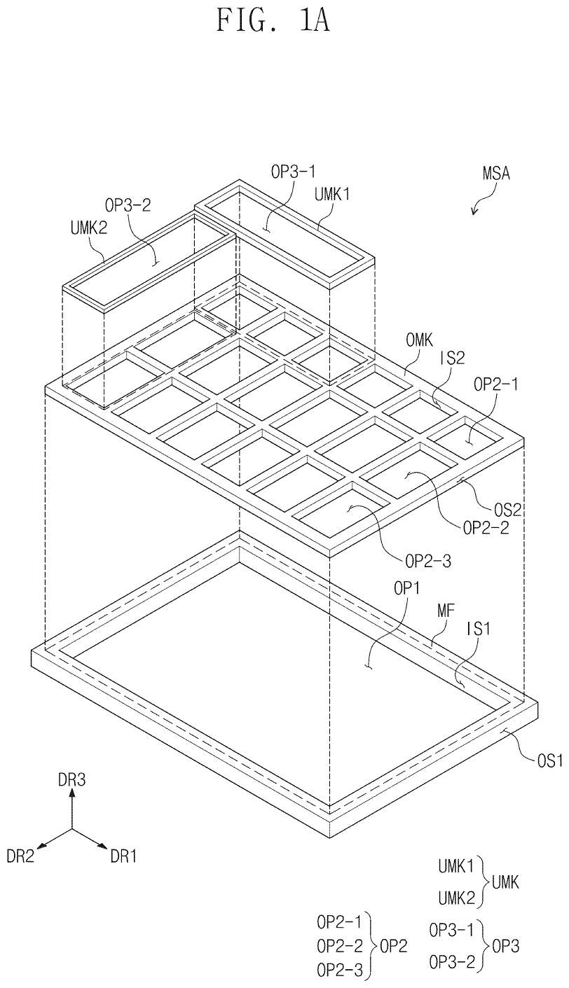

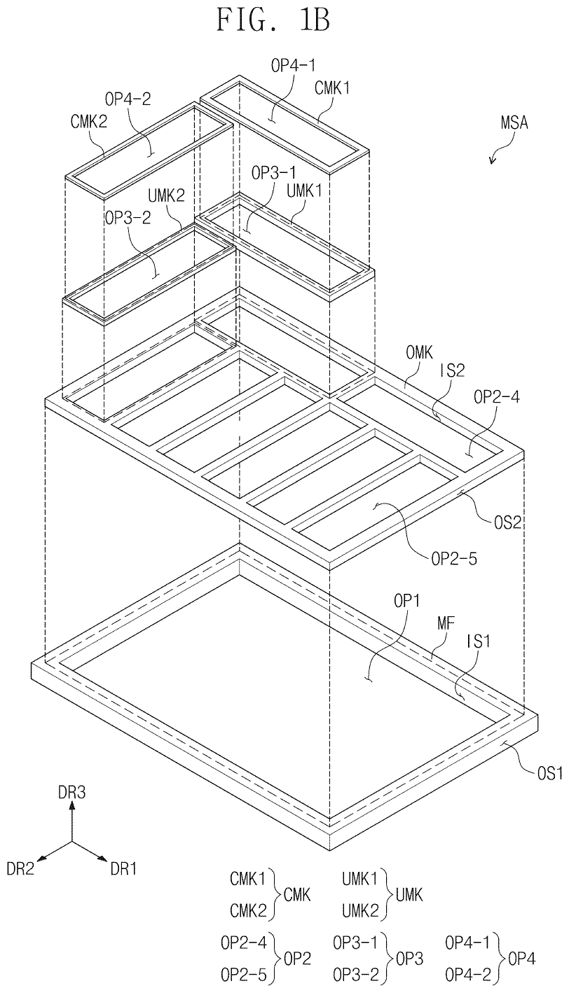

Each of FIGS. 1A and 1B is an exploded perspective view illustrating a mask assembly according to one or more embodiments of the present disclosure. Compared to FIG. 1B, some components of the mask assembly are omitted in FIG. 1A. For example, FIG. 1A illustrates a state in which cell masks are not located on an open mask and unit masks.

Referring to FIGS. 1A and 1B, the mask assembly MSA according to one or more embodiments of the present disclosure may include a mask frame MF, an open mask OMK, a plurality of unit masks UMK, and a plurality of cell masks CMK. The mask assembly MSA may be used to form a common layer of light-emitting elements of a display device. The common layer may be an electron control layer, a hole control layer, and/or a cathode of the light-emitting elements.

The mask frame MF may have a tetragonal frame shape having long sides extending in a first direction DR1, and short sides extending in a second direction DR2 crossing the first direction DR1, but the shape of the mask frame MF is not limited thereto.

Hereinafter, a direction crossing a plane defined by the first and second directions DR1 and DR2 is defined as a third direction DR3. The third direction DR3 may substantially perpendicularly cross a plane defined by the first and second directions DR1 and DR2. A cross section refers to a surface parallel to the third direction DR3, and a plane means a surface perpendicular to the thickness direction DR3. In this specification, the expression “when viewed on a plane,” or “in plan view,” may refer to a state of being viewed in the third direction DR3.

In this specification, the thickness direction of the mask assembly MSA may be parallel to the third direction DR3. A front surface (or top surface) and a rear surface (or bottom surface) may be opposite each other in the third direction DR3, and the normal directions of the front surface (or top surface) and the rear surface (or bottom surface) may be parallel to the third direction DR3. Directions indicated by the first to third directions DR1, DR2, and DR3 described in this specification are relative concepts, and may be converted into other directions.

A first opening OP1 may be defined in the mask frame MF according to the frame shape of the mask frame MF. On a plane, the first opening OP1 may have a tetragonal shape, but the shape of the first opening OP1 is not limited thereto.

The side surfaces of the mask frame MF facing the outside may include side surfaces extending in the first direction DR1, and side surfaces extending in the second direction DR2. The side surfaces of the mask frame MF facing the outside may be defined as an outer side surface OS1 (hereinafter referred to as a “first outer side surface”). The first outer side surface OS1 of the mask frame MF may be defined as an edge of the mask frame MF.

An inner side surface IS1 (hereinafter referred to as a “first inner side surface”) of the mask frame MF may be defined by the side surface facing the first outer side surface OS1 of the mask frame MF. The first opening OP1 may be defined by the first inner side surface IS1 of the mask frame MF.

The mask frame MF may contain a metal material. For example, the mask frame MF may contain stainless steel or an INVAR® alloy (INVAR is a registered trademark of Aperam Alloys IMPHY Joint Stock Company).

The open mask OMK may be located on the mask frame MF. The open mask OMK may have a plane defined by the first and second directions DR1 and DR2. The open mask OMK may have a tetragonal shape having long sides extending in the first direction DR1 and short sides extending in the second direction DR2, but the shape of the open mask OMK is not limited thereto.

A plurality of second openings OP2 may be defined in the open mask OMK. The second openings OP2 may be arranged in the first and second directions DR1 and DR2. On a plane, the second openings OP2 may overlap the first opening OP1. That is, the second openings OP2 may be located in, or may overlap, the first opening OP1 on a plane. On a plane, the second openings OP2 may have a tetragonal shape, but the shapes of the second openings OP2 are not limited thereto.

FIG. 1A illustrates 18 second openings OP2 arranged in 3 rows and 6 columns, and FIG. 1B illustrates 8 second openings OP2 arranged in 2 rows, and in both 2 columns and 6 columns, but the shapes of the second openings OP2 are not limited thereto. The row may correspond to the first direction DR1, and the column may correspond to the second direction DR2.

When at least a portion of the open mask OMK is removed during a manufacturing process of the mask assembly MSA in a state in which 18 second openings OP2 are defined in the open mask OMK, as illustrated in FIG. 1A, the number of the second openings OP2 defined in the open mask OMK may be reduced to 12, as described in FIG. 1B. For example, when a portion of the open mask OMK dividing adjacent second openings OP2 is removed in a state in which a cell mask CMK is not located on the open mask OMK, two or three adjacent second openings OP2 may be formed as an integral opening so that the total number of the second openings OP2 defined in the open mask OMK may be reduced.

Some of the side surfaces of the open mask OMK facing the outside may extend in the first direction DR1, and others may extend in the second direction DR2. The side surfaces of the open mask OMK facing the outside may be defined as a second outer side surface OS2. The second outer side surface OS2 of the open mask OMK may be defined as an edge of the open mask OMK. The surfaces of the open mask OMK defining the second openings OP2 may be defined as second inner side surfaces IS2 of the open mask OMK.

In one or more embodiments of the present disclosure, at least one of the second openings OP2 defined by the second inner side surfaces IS2 of the open mask OMK may have a shape that is different from the shapes of the rest thereof. Referring to FIG. 1A, in a state in which the cell mask CMK is not located on the open mask OMK, the second openings OP2 are spaced apart from each other in the second direction DR2, and may respectively include (2-1)-th openings OP2-1, (2-2)-th openings OP2-2, and (2-3)-th openings OP2-3 arranged along the second direction DR2.

At least one of the (2-1)-th openings OP2-1, the (2-2)-th openings OP2-2, and the (2-3)-th openings OP2-3 may have a shape that is different from the shapes of the rest thereof. When viewed on a plane, the widths or lengths of the (2-1)-th openings OP2-1, the (2-2)-th openings OP2-2, and the (2-3)-th openings OP2-3 may be the same as each other in the first direction DR1, and may be different from one or more of each other in the second direction DR2. For example, each of the (2-2)-th openings OP2-2 and the (2-3)-th openings OP2-3 may have a tetragonal shape extending longer than the (2-1)-th openings OP2-1 in the second direction DR2, but the shapes of the (2-1)-th to (2-3)-th openings OP2-1, OP2-2, and OP2-3 are not limited thereto.

In a state in which the cell mask CMK is located on the open mask OMK, a plurality of (2-1)-th openings OP2-1 adjacent to each other in the first direction DR1 may form an integral opening, and the (2-2)-th opening OP2-2 and the (2-3)-th opening OP2-3 adjacent to each other in the second direction DR2 may form an integral opening. For example, during a manufacturing process of the mask assembly MSA, at least a portion of the open mask OMK dividing the (2-1)-th openings OP2-1 may be removed, so that three adjacent (2-1)-th openings OP2-1 may form an integral opening. In addition, at least portions of the open mask OMK dividing the (2-2)-th openings OP2-2 and the (2-3)-th openings OP2-3 may be removed, so that one (2-2)-th opening OP2-2 and one (2-3)-th opening OP2-3 adjacent to each other in the second direction DR2 may form an integral opening.

Referring to FIG. 1B, in a state in which the cell masks CMK are located on the open mask OMK, a plurality of (2-4)-th openings OP2-4 and a plurality of (2-5)-th openings OP2-5, which are arranged in the first direction DR1 and spaced apart from each other along the second direction DR2, may be defined in the open mask OMK. Each of the (2-4)-th openings OP2-4 may correspond to three (2-1)-th openings OP2-1 (see FIG. 1A) forming an integral opening, and each of the (2-5)-th openings OP2-5 may correspond to a (2-2)-th opening OP2-2 (see FIG. 1A) and a 2-3rd opening OP2-3 (see FIG. 1A) forming an integral opening.

The (2-4)-th openings OP2-4 and the (2-5)-th openings OP2-5 may have different widths in the first and second directions DR1 and DR2. For example, in the first direction DR1, the width of the (2-4)-th openings OP2-4 may be greater than the width of the (2-5)-th openings OP2-5. In addition, in the second direction DR2, the width of the (2-4)-th openings OP2-4 may be less than the width of the (2-5)-th openings OP2-5.

When viewed on a plane, in a state in which the cell mask CMK is located on the open mask OMK, the areas of the second openings OP2 may be substantially the same as each other. That is, on a plane, the areas of the (2-4)-th openings OP2-4 and the (2-5)-th openings OP2-5 may be substantially the same as each other. In this specification, being substantially the same as each other includes not only a case in which physical values are the same as each other, but also a case in which there is a difference within an error range in a process.

Based on the third direction DR3, the open mask OMK may have a thickness that is less than a thickness of the mask frame MF. For example, the open mask OMK may have a thickness of about 100 micrometers (μm) to about 150 μm.

The open mask OMK may contain the same material as the mask frame MF. For example, the open mask OMK may contain a metal material, and, for example, the open mask OMK may contain stainless steel or an INVAR® alloy (INVAR is a registered trademark of Aperam Alloys IMPHY Joint Stock Company).

The open mask OMK may be coupled to the mask frame MF by welding. For example, a portion of the open mask OMK adjacent to the edge of the open mask OMK may be coupled to the mask frame MF by laser welding. The open mask OMK may be supported by the mask frame MF.

The unit masks UMK may be located on the open mask OMK. The unit masks UMK may have a plane defined by the first and second directions DR1 and DR2. The unit masks UMK may include a first unit mask UMK1 and a second unit mask UMK2. The first unit mask UMK1 and the second unit mask UMK2 may be provided in plurality. The first unit mask UMK1 may have a tetragonal frame shape having long sides extending in the first direction DR1, and short sides extending in the second direction DR2. The second unit mask UMK2 may have a tetragonal frame shape having short sides extending in the first direction DR1 and long sides extending in the second direction DR2. However, the shapes of the first and second unit masks UMK1 and UMK2 are not limited thereto.

The unit masks UMK may be arranged in the first and second directions DR1 and DR2. A plurality of first unit masks UMK1 and a plurality of second unit masks UMK2 may be arranged in the first direction DR1, and may be spaced apart from each other in the second direction DR2. The unit masks UMK may be prepared in a smaller number than the second openings OP2. For example, the first unit masks UMK1 and the second unit masks UMK2 may be prepared in a smaller number than the (2-1)-th openings OP2-1, the (2-2)-th openings OP2-2, and the (2-3)-th openings OP2-3.

In a state in which the cell masks CMK are located on the unit masks UMK, the first unit masks UMK1 may respectively correspond to a plurality of (2-1)-th openings OP2-1, and each of the second unit masks UMK2 may correspond to one (2-2)-th opening OP2-2 and one (2-3)-th opening OP2-3. For example, each of the first unit masks UMK1 may be located on three corresponding (2-1)-th openings OP2-1 among the (2-1)-th openings OP2-1, and each of the second unit masks UMK2 may be located on a corresponding (2-2)-th opening OP2-2 and a corresponding (2-3)-th opening OP2-3. Accordingly, on a plane, the first unit masks UMK1 may overlap three (2-1)-th openings OP2-1, and the second unit masks UMK2 may overlap one (2-2)-th opening OP2-2 and one (2-3)-th opening OP2-3.

Referring to FIG. 1B, in a state in which the cell masks CMK are located on the unit masks UMK, the number of the unit masks UMK may be the same as the number of the second openings OP2. For example, the first unit masks UMK1 may be arranged in one row and two columns, and the second unit masks UMK2 may be arranged in one row and six columns. As described above, because three (2-1)-th openings OP2-1 forms an integral opening, and one (2-2)-th opening OP2-2 and one (2-3)-th opening OP2-3 form an integral opening during a manufacturing process of the mask assembly MSA, the number of the unit masks UMK may be the same as the number of the second openings OP2.

The unit masks UMK may respectively correspond to the second openings OP2. For example, in a state in which the cell masks CMK are located on the unit masks UMK, the first unit masks UMK1 may be respectively located on corresponding (2-4)-th openings OP2-4 among the (2-4)-th openings OP2-4, and the second unit masks UMK2 may be respectively located on corresponding (2-5)-th openings OP2-5 among the (2-5)-th openings OP2-5. Accordingly, on a plane, the unit masks UMK may respectively overlap the second openings OP2.

A unit opening OP3 may be defined in each of the unit masks UMK. For example, a first unit opening OP3-1 may be defined in each of the first unit masks UMK1, and a second unit opening OP3-2 may be defined in each of the second unit masks UMK2. Because each of the first unit openings OP3-1 may overlap a plurality of (2-1)-th openings OP2-1 and a portion of the open mask OMK is removed during a manufacturing process, the first unit openings OP3-1 may respectively overlap the (2-4)-th openings OP2-4. In addition, because each of the second unit openings OP3-2 may overlap the (2-2) openings OP2-2 and the (2-3)-th openings OP2-3, and because a portion of the open mask OMK is removed during a manufacturing process, the second unit openings OP3-2 may respectively overlap the (2-5)-th openings OP2-5. Each of the first unit openings OP3-1 may have a tetragonal shape extending lengthwise in the first direction DR1, and each of the second unit openings OP3-2 may have a tetragonal shape extending lengthwise in the second direction DR2, but the shapes of the first unit openings OP3-1 and the second unit openings OP3-2 are not limited thereto.

The side surfaces of each of the first unit masks UMK1 and the second unit masks UMK2 facing the outside may include side surfaces extending in the first direction DR1 and side surfaces extending in the second direction DR2. The side surfaces of each of the first unit masks UMK1 and the second unit masks UMK2 facing the outside may be defined as an outer side surface. In the first unit masks UMK1, the side surfaces extending in the first direction DR1 may have a greater length than the side surfaces extending in the second direction DR2. In the second unit masks UMK2, the side surfaces extending in the first direction DR1 may have a length that is less than a length of the side surfaces extending in the second direction DR2.

An inner side surface of each of the unit masks UMK may be defined by the side surfaces opposite to the outer side surface of each of the unit masks UMK. The unit opening OP3 may be defined by the inner side surfaces of each of the unit masks UMK. For example, the first unit opening OP3-1 may be defined by the inner side surfaces of the first unit mask UMK1, and the second unit opening OP3-2 may be defined by the inner side surfaces of the second unit mask UMK2.

Based on the third direction DR3, each of the unit masks UMK may have a thickness that is less than a thickness of the open mask OMK. In addition, the unit masks UMK may contain the same material as the open mask OMK. For example, the unit masks UMK may contain a metal material, and, for example, the unit masks UMK may contain stainless steel or an INVAR® alloy (INVAR is a registered trademark of Aperam Alloys IMPHY Joint Stock Company).

The unit masks UMK may be coupled to the open mask OMK by welding. For example, portions of the unit masks UMK adjacent to edges of the unit masks UMK may be coupled to the open mask OMK by laser welding. Without being limited thereto, however, the unit masks UMK may be attached to the open mask OMK by an adhesive. The unit masks UMK may be supported by the open mask OMK.

Referring to FIG. 1B, the cell masks CMK may be located on the unit masks UMK. The cell masks CMK may have a plane defined by first and second directions DR1 and DR2. The cell masks CMK may include first cell masks CMK1 and second cell masks CMK2. The first cell masks CMK1 may have a tetragonal frame shape having long sides extending in the first direction DR1, and short sides extending in the second direction DR2. The second cell masks CMK2 may have a tetragonal frame shape having long sides extending in the second direction DR2, and short sides extending in the first direction DR1. However, the shapes of the cell masks CMK are not limited thereto.

The cell masks CMK may be arranged in the first and second directions DR1 and DR2. The first cell masks CMK1 and the second cell masks CMK2 may be arranged in the first direction DR1 and spaced apart from each other in the second direction DR2. The cell masks CMK may be prepared in the same number as the unit openings OP3. For example, the first cell masks CMK1 may be prepared in the same number as the first unit openings OP3-1, and the second cell masks CMK2 may be prepared in the same number as the second unit openings OP3-2. The first cell masks CMK1 may be arranged in one row and two columns so as to correspond to the first unit openings OP3-1. The second cell masks CMK2 may be arranged in one row and six columns so as to correspond to the second unit openings OP3-2.

The cell masks CMK may respectively correspond to the unit openings OP3. Each of the cell masks CMK may be located on a corresponding unit opening OP3 among the unit openings OP3. For example, each of the first cell masks CMK1 may be located on a corresponding first unit opening OP3-1 among the first unit openings OP3-1, and each of the second cell masks CMK2 may be located on a corresponding second unit opening OP3-2 among the second unit openings OP3-2. Accordingly, when viewed on a plane, the first cell masks CMK1 may respectively overlap the first unit openings OP3-1, and the second cell masks CMK2 may respectively overlap the second unit openings OP3-2.

A cell opening OP4 may be defined in each of the cell masks CMK. A first cell opening OP4-1 may be defined in each of the first cell masks CMK1, and a second cell opening OP4-2 may be defined in each of the second cell masks CMK2. When viewed on a plane, the first cell openings OP4-1 may respectively overlap the first unit openings OP3-1, and the second cell openings OP4-2 may respectively overlap the second unit openings OP3-2. Each of the first cell openings OP4-1 may have a tetragonal shape extending lengthwise in the first direction DR1, and each of the second cell openings OP4-2 may have a tetragonal shape extending lengthwise in the second direction DR2, but the shapes of the first cell openings OP4-1 and the second cell openings OP4-2 are not limited thereto.

The side surfaces of each of the cell masks CMK facing the outside may include side surfaces extending in the first direction DR1 and side surfaces extending in the second direction DR2. The side surfaces of each of the cell masks CMK facing the outside may be defined as an outer side surface. The outer side surface of each of the cell masks CMK may be defined as an edge of each of the cell masks CMK.

An inner side surface of each of the cell masks CMK may be defined by the side surfaces opposite to the outer side surface of each of the cell masks CMK. The cell opening OP4 may be defined by the inner side surfaces of each of the cell masks CMK.

Based on the third direction DR3, each of the cell masks CMK may have a thickness that is less than a thickness of the open mask OMK. For example, each of the cell masks CMK may have a thickness of about 10 μm to about 50 μm.

The cell masks CMK may contain the same material as the open mask OMK and the unit mask UMK. For example, the cell masks CMK may contain a metal material, and, for example, the cell masks CMK may contain stainless steel or an INVAR® alloy (INVAR is a registered trademark of Aperam Alloys IMPHY Joint Stock Company).

The cell masks CMK may be coupled to the unit mask UMK by welding. For example, portions of the cell masks CMK adjacent to edges of the cell masks CMK may be coupled to the unit mask UMK by laser welding. Without being limited thereto, however, the cell masks CMK may be attached to the unit mask UMK by an adhesive. The cell masks CMK may be supported by the unit mask UMK.

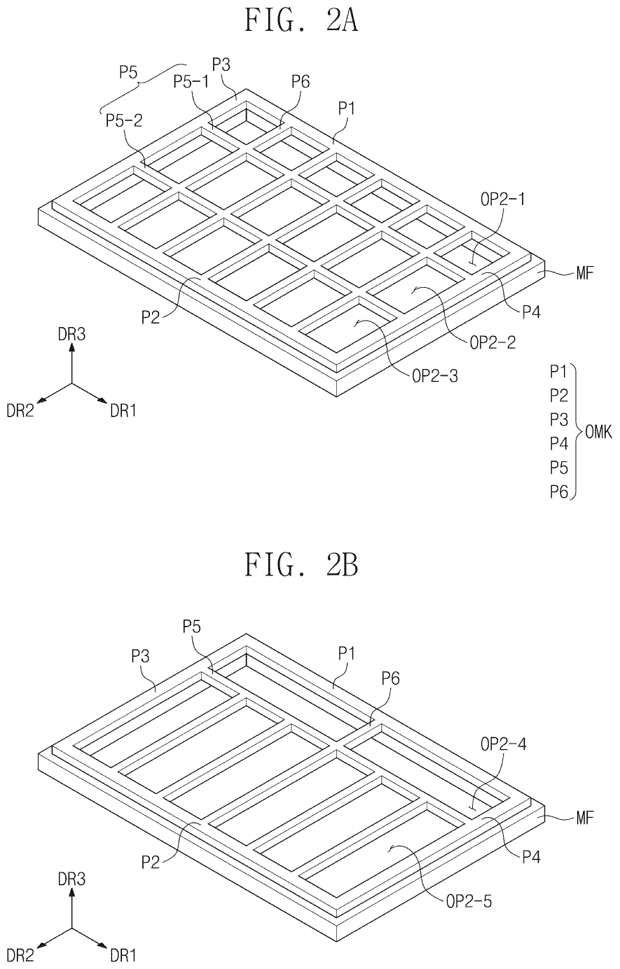

Each of FIGS. 2A and 2B is a perspective view of some components of the mask assembly combined according to one or more embodiments of the present disclosure. FIG. 2A is a perspective view of the mask frame MF and the open mask OMK illustrated in FIG. 1A combined, and FIG. 2B is a perspective view of the mask frame MF and the open mask OMK illustrated in FIG. 1B combined.

Referring to FIGS. 2A and 2B, the open mask OMK may be coupled to a top surface of the mask frame MF. In one or more embodiments of the present disclosure, the open mask OMK may include a first portion P1, a second portion P2, a third portion P3, a fourth portion P4, a fifth portion P5, and a sixth portion P6. The open mask OMK may have a structure in which the first to sixth portions P1 to P6 are organically connected to each other.

The first portion P1 and the second portion P2 may each extend in the first direction DR1. The first portion P1 and the second portion P2 may be spaced apart from each other in the second direction DR2. The third portion P3 and the fourth portion P4 may each extend in the second direction DR2. The third portion P3 may connect one end of the first portion P1 and one end of the second portion P2 to each other. The fourth portion P4 may connect the other end of the first portion P1 and the other end of the second portion P2 to each other. The first to fourth portions P1, P2, P3, and P4 may be connected to each other to form an exterior of the open mask OMK.

The fifth portion P5 extends in the first direction DR1 and may be provided in plurality along the second direction DR2. In the second direction DR2, a plurality of fifth portions P5 may be arranged to be spaced apart from each other between the first portion P1 and the second portion P2. One end and the other end of each of the fifth portions P5 may be respectively connected to the third portion P3 and the fourth portion P4.

Referring to FIG. 2A, the fifth portions P5 may include a (5-1)-th portion P5-1 and a (5-2)-th portion P5-2 arranged along the second direction DR2. In the open mask OMK, the second openings OP2 may be arranged in three rows divided by the (5-1)-th portion P5-1 and the (5-2)-th portion P5-2.

In the second direction DR2, the (5-1)-th portion P5-1 may be located closer to the first portion P1 than the (5-2)-th portion P5-2. In addition, in the second direction DR2, the (5-1)-th portion P5-1 may be located farther away from the second portion P2 than the (5-2)-th portion P5-2. For example, the (5-1)-th portion P5-1 may divide the (2-1)-th openings OP2-1 and the (2-2)-th openings OP2-2 that are adjacent thereto. The (5-2)-th portion P5-2 may divide the (2-2)-th openings OP2-2 and the (2-3)-th openings OP2-3 that are adjacent thereto.

The sixth portion P6 extends in the second direction DR2 and may be provided in plurality along the first direction DR1. In the first direction DR1, a plurality of sixth portions P6 may be arranged to be spaced apart from each other between the third portion P3 and the fourth portion P4. For example, as illustrated in FIG. 2A, five sixth portions P6 are arranged along the first direction DR1 between the third portion P3 and the fourth portion P4 so that the second openings OP2 of the open mask OMK may be arranged in six columns. The plurality of sixth portions P6 arranged along the first direction DR1 may respectively divide the (2-1)-th openings OP2-1, the (2-2)-th openings OP2-2, and the (2-3)-th openings OP2-3 that are adjacent thereto. One end and the other end of the sixth portions P6 may be respectively connected to the first portion P1 and the second portion P2.

Referring to FIG. 2A, the first portion P1, the third portion P3, the fourth portion P4, the (5-1)-th portion P5-1, and the sixth portion P6 may define the (2-1)-th openings OP2-1 of the open mask OMK. The third portion P3, the fourth portion P4, the (5-1)-th portion P5-1, the (5-2)-th portion P5-2, and the sixth portion P6 may define the (2-2)-th openings OP2-2. In addition, the second portion P2, the third portion P3, the fourth portion P4, the (5-2)-th portion P5-2, and the sixth portion P6 may define the (2-3)-th openings OP2-3.

As described above, when manufacturing the mask assembly MSA according to one or more embodiments of the present disclosure, at least a portion of the open mask OMK may be removed before the cell mask CMK (see FIG. 1B) is located on the unit mask UMK (see FIG. 1B).

For example, referring to FIGS. 2A and 2B together, the (5-2)-th portion P5-2 located between the (2-2)-th openings OP2-2 and the (2-3)-th openings OP2-3 may be removed among the fifth portions P5 of the open mask OMK. Accordingly, the (2-2)-th opening OP2-2 and the (2-3)-th opening OP2-3 adjacent to each other in the second direction DR2 may form an integral opening so as to be converted into one (2-5)-th opening OP2-5. In the first direction DR1, a width of the (2-5)-th opening OP2-5 may be substantially the same as a width of each of the (2-2)-th opening OP2-2 and the (2-3)-th opening OP2-3. Meanwhile, in the second direction DR2, a width of the (2-5)-th opening OP2-5 may be greater than the sum of widths of the (2-2)-th opening OP2-2 and the (2-3)-th opening OP2-3.

In addition, at least a portion of the sixth portion P6 of the open mask OMK located between the (2-1)-th openings OP2-1 adjacent to each other may be removed. For example, a portion of two sixth portions P6 located between three adjacent (2-1)-th openings OP2-1 may be removed. Accordingly, the plurality of (2-1)-th openings OP2-1 may form an integral opening so as to be converted into one (2-4)-th openings OP2-4. A width of the (2-4)-th opening OP2-4 may be greater than the sum of widths of the three (2-1)-th openings OP2-1 in the first direction DR1, but the present disclosure is not limited thereto. Meanwhile, in the second direction DR2, a width of the (2-4)-th opening OP2-4 may be the same as that of each of the (2-1)-th openings OP2-1.

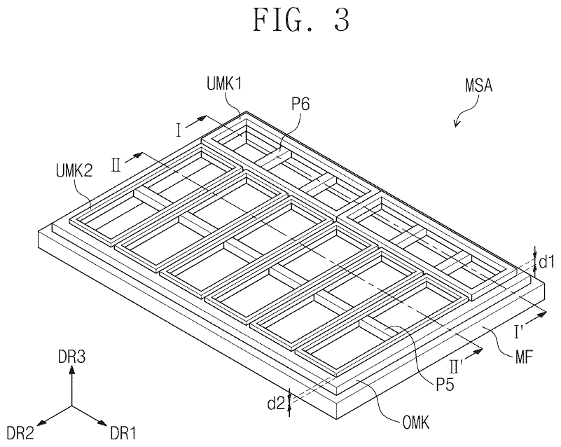

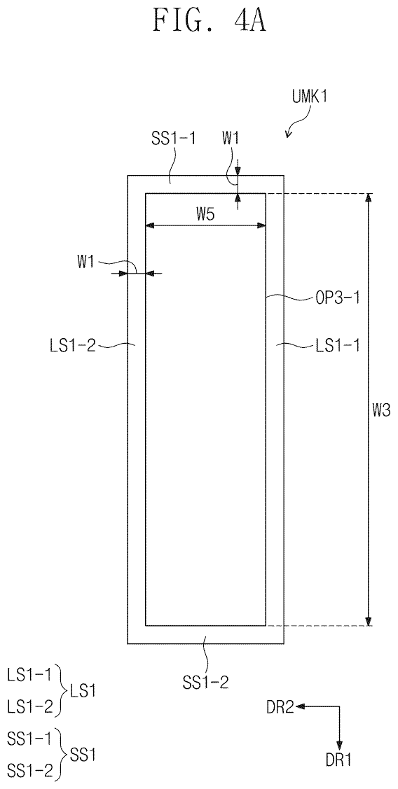

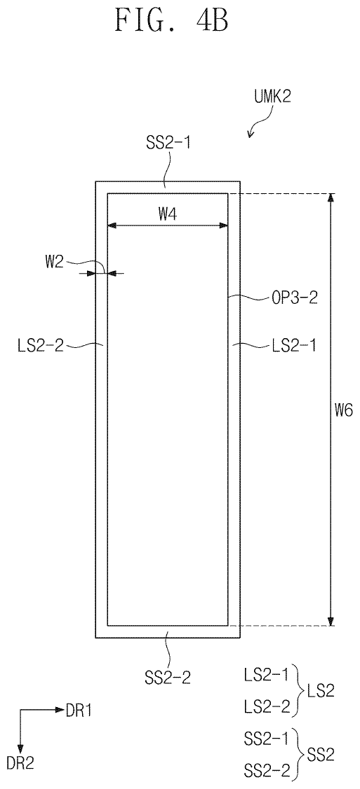

FIG. 3 is a perspective view of some components of the mask assembly combined according to one or more embodiments of the present disclosure. FIG. 3 illustrates a state in which the mask frame MF, the open mask OMK, and the unit masks UMK illustrated in FIG. 1A. Each of FIGS. 4A and 4B is a plan view illustrating some components of the mask assembly according to one or more embodiments of the present disclosure. FIG. 4A illustrates a first unit mask UMK1 among the unit masks UMK, and FIG. 4B illustrates a second unit mask UMK2 among the unit masks UMK.

Referring to FIGS. 1A and 3, the first unit mask UMK1 and the second unit mask UMK2 may be coupled to a top surface of the open mask OMK in which the (2-1)-th to (2-3)-th openings OP2-1, OP2-2, and OP2-3 are defined. The first unit mask UMK1 may correspond to three (2-1)-th openings OP2-1 arranged in the first direction DR1, and the second unit mask UMK2 may correspond to one of the (2-2)-th openings OP2-2 and one of the (2-3)-th openings OP2-3 arranged in the second direction DR2.

In one or more embodiments of the present disclosure, the sixth portion P6 exposed to the outside through the first unit opening OP3-1 of the first unit mask UMK1, and the fifth portion P5 exposed to the outside through the second unit opening OP3-2 of the second unit mask UMK2, may be removed. For example, before coupling the cell masks CMK onto the unit masks UMK when manufacturing the mask assembly MSA, the sixth portion P6 exposed to the outside through the first unit opening OP3-1 and the fifth portion P5 exposed to the outside through the second unit opening OP3-2 may be removed.

Referring to FIG. 3, the first unit mask UMK1 may have a first thickness d1, and the second unit mask UMK2 may have a second thickness d2. In the third direction DR3, the first thickness d1 of the first unit mask UMK1 and the second thickness d2 of the second unit mask UMK2 may be different from each other. For example, the first thickness d1 may be greater than the second thickness d2. Because the thickness of the first unit mask UMK1, which has a greater width than the second unit mask UMK2 in the first direction DR1, is formed to be greater than the thickness of the second unit mask UMK2, shrinkage force may be uniformly distributed in a process of coupling the unit masks UMK to the open mask OMK, thus preventing sagging of the fifth and sixth portions P5 and P6 of the open mask.

Referring to FIGS. 3 and 4A, the first unit mask UMK1 may include two first long side portions LS1 extending in the first direction DR1, and two first short side portions SS1 extending in the second direction DR2. For example, each of the first short side portions SS1 may include a (1-1)-th short side portion SS1-1 and a (1-2)-th short side portion SS1-2 extending in the second direction DR2, and spaced apart from each other in the first direction DR1. In addition, the first long side portions LS1 may include a (1-1)-th long side portion LS1-1 and a (1-2)-th long side portion LS1-2 spaced apart from each other in the second direction DR2.

The (1-1)-th short side portion SS1-1 may connect one end of the (1-1)-th long side portion LS1-1 and one end of the (1-2)-th long side portion LS1-2 to each other, and the (1-2)-th short side portion SS1-2 may connect the other end of the (1-1)-th long side portion LS1-1 and the other end of the (1-2)-th long side portion LS1-2 to each other. The (1-1)-th short side portion SS1-1, the (1-2)-th short side portion SS1-2, the (1-1)-th long side portion LS1-1, and the (1-2)-th long side portion LS1-2 may be connected to each other to form an exterior of the first unit mask UMK1, and may define the first unit opening OP3-1.

Two first short side portions SS1 and two first long side portions LS1 may have the same width as each other. For example, each of the (1-1)-th short side portion SS1-1, the (1-2)-th short side portion SS1-2, the (1-1)-th long side portion LS1-1, and the (1-2)-th long side portion LS1-2 may have a same first width W1. The first width W1 may be about 100 μm to about 150 μm, but the present disclosure is not limited thereto.

The (1-1)-th short side portion SS1-1 and the (1-2)-th short side portion SS1-2 may be spaced apart from each other by a distance (e.g., predetermined distance) in the first direction DR1. The distance between the (1-1)-th short side portion SS1-1 and the (1-2)-th short side portion SS1-2 spaced apart from each other in the first direction DR1 may correspond to a third width W3 of the first unit opening OP3-1. In addition, the (1-1)-th long side portion LS1-1 and the (1-2)-th long side portion LS1-2 may be spaced apart from each other by a distance (e.g., predetermined distance) in the second direction DR2. The distance between the (1-1)-th long side portion LS1-1 and the (1-2)-th long side portion LS1-2 may correspond to a fifth width W5 of the first unit opening OP3-1. The third width W3 of the first unit opening OP3-1 may be a width in the first direction DR1, and the fifth width W5 may be a width in the second direction DR2. The third width W3 may be greater than the fifth width W5.

Referring to FIGS. 3 and 4B, the second unit mask UMK2 may include two second short side portions SS2 extending in the first direction DR1 and two second long side portions LS2 extending in the second direction DR2. For example, each of the second short side portions SS2 may include a (2-1)-th short side portion SS2-1 and a (2-2)-th short side portion SS2-2 extending in the first direction DR1 and spaced apart from each other in the second direction DR2. In addition, each of the second long side portions LS2 may include a (2-1)-th long side portion LS2-1 and a (2-2)-th long side portion LS2-2 extending in the second direction DR2 and spaced apart from each other in the first direction DR1.

The (2-1)-th short side portion SS2-1 may connect one end of the (2-1)-th long side portion LS2-1 and one end of the (2-2)-th long side portion LS2-2 to each other, and the (2-2)-th short side portion SS2-2 may connect the other end of the (2-1)-th long side portion LS2-1 and the other end of the (2-2)-th long side portion LS2-2 to each other. The (2-1)-th short side portion SS2-1, the (2-2)-th short side portion SS2-2, the (2-1)-th long side portion LS2-1, and the (2-2)-th long side portion LS2-2 may be connected to each other to form an exterior of the second unit mask UMK2, and may define the second unit opening OP3-2. Two second short side portions SS2 and two second long side portions LS2 may have the same width as each other. For example, each of the (2-1)-th short side portion SS2-1, the (2-2)-th short side portion SS2-2, the (2-1)-th long side portion LS2-1, and the (2-2)-th long side portion LS2-2 may have a same second width W2.

In one or more embodiments of the present disclosure, the first width W1 (see FIG. 4A) may be greater than the second width W2. Accordingly, in one direction, the length of the first long side portions LS1 may be greater than the length of the second long side portions LS2. In addition, in one direction, the length of the first short side portions SS1 may be greater than the length of the second short side portions SS2.

The (2-1)-th long side portion LS2-1 and the (2-2)-th long side portion LS2-2 may be spaced apart from each other by a distance (e.g., predetermined distance) in the first direction DR1. The distance between the (2-1)-th long side portion LS2-1 and the (2-2)-th long side portion LS2-2 may correspond to a fourth width W4 of the second unit opening OP3-2. In addition, the (2-1)-th short side portion SS2-1 and the (2-2)-th short side portion SS2-2 may be spaced apart from each other by a distance (e.g., predetermined distance) in the second direction DR2. The distance between the (2-1)-th short side portion SS2-1 and the (2-2)-th short side portion SS2-2 spaced apart from each other in the second direction DR2 may correspond to a sixth width W6 of the second unit opening OP3-2. The fourth width W4 of the second unit opening OP3-2 may be a width in the first direction DR1, and the sixth width W6 may be a width in the second direction DR2. The fourth width W4 may be less than the sixth width W6.

Referring to FIGS. 4A and 4B together, the fourth width W4 and the fifth width W5 may be substantially the same as each other, and the third width W3 and the sixth width W6 may be substantially the same as each other. Accordingly, on a plane, the first unit opening OP3-1 and the second unit opening OP3-2 may have substantially the same area as each other.

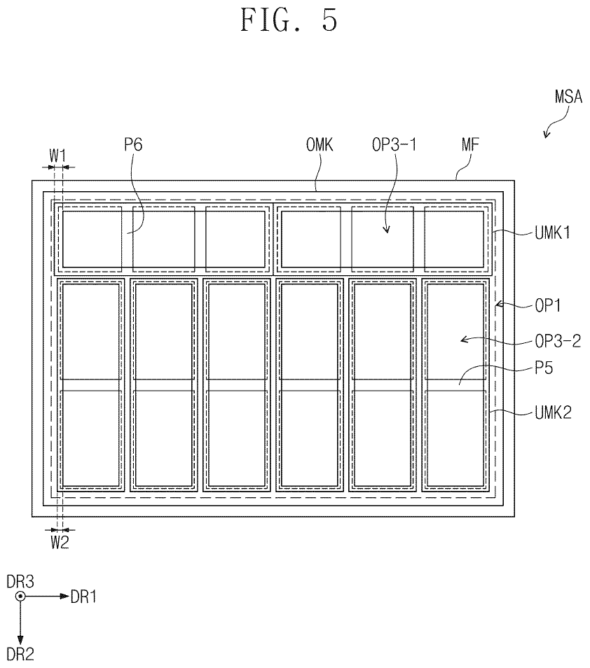

FIG. 5 is a plan view illustrating some components of the mask assembly according to one or more embodiments of the present disclosure. FIG. 5 is a plan view of the mask assembly MSA illustrated in FIG. 3. Each of FIGS. 6A and 6B is a cross-sectional view illustrating some components of the mask assembly according to one or more embodiments of the present disclosure. FIG. 6A is a cross-sectional view of a portion taken along the line I-I′ of FIG. 3, and FIG. 6B is a cross-sectional view of a portion taken along the line II-II′ of FIG. 3.

Referring to FIG. 5, the first width W1 of the first unit mask UMK1 may be greater than the second width W2 of the second unit mask UMK2. For example, the first width W1 may be about 1.1 times to about 1.5 times greater than the second width W2, but the present disclosure is not limited thereto. Meanwhile, FIG. 5 illustrates a structure in which each of the first unit masks UMK1 and the second unit masks UMK2 is arranged in one row along the first direction DR1, but without being limited thereto, the first unit masks UMK1 may be arranged in two rows with the second unit masks UMK2 interposed therebetween.

Referring to FIGS. 5 to 6B, a plurality of unit masks UMK may be provided on the top surface of the open mask OMK. For example, two first unit masks UMK1 and six second unit masks UMK2 may be coupled to each other on the top surface of the open mask OMK. The first unit masks UMK1 and the second unit masks UMK2 may be arranged in the first direction DR1. In addition, the first unit masks UMK1 and the second unit masks UMK2 may be spaced apart from each other in the second direction DR2.

In the first direction DR1, a width of each of the first unit masks UMK1 may be greater than that of each of the second unit masks UMK2. In addition, in the second direction DR2, a width of each of the first unit masks UMK1 may be less than that of each of the second unit masks UMK2, but the present disclosure is not limited thereto.

Referring to FIGS. 5 to 6B, a plurality of second unit masks UMK2 may correspond to one first unit mask UMK1 in the first direction DR1. For example, three second unit masks UMK2 may be arranged to correspond to one first unit mask UMK1. In addition, six second unit masks UMK2 may be arranged to correspond to two first unit masks UMK1. Accordingly, based on a half cut method, about 8 display panels may be manufactured from one sheet of glass, and based on a mother glass, about 16 display panels may be manufactured. By using the mask assembly MSA according to one or more embodiments of the present disclosure, the number of display panels that may be manufactured from a mother glass may be increased as compared to a typical mask assembly in which openings having substantially the same size and shape as each other are arranged in one direction, thereby being able to reduce costs.

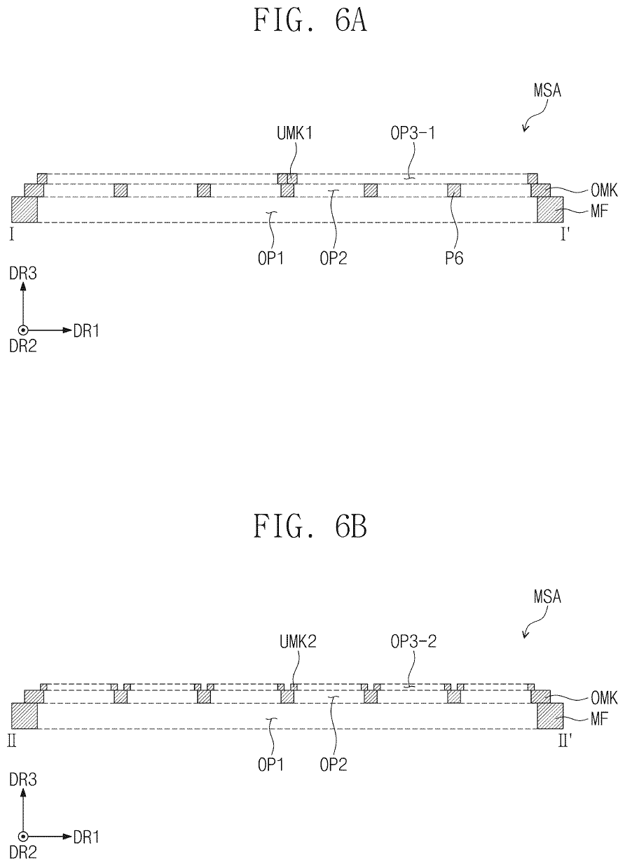

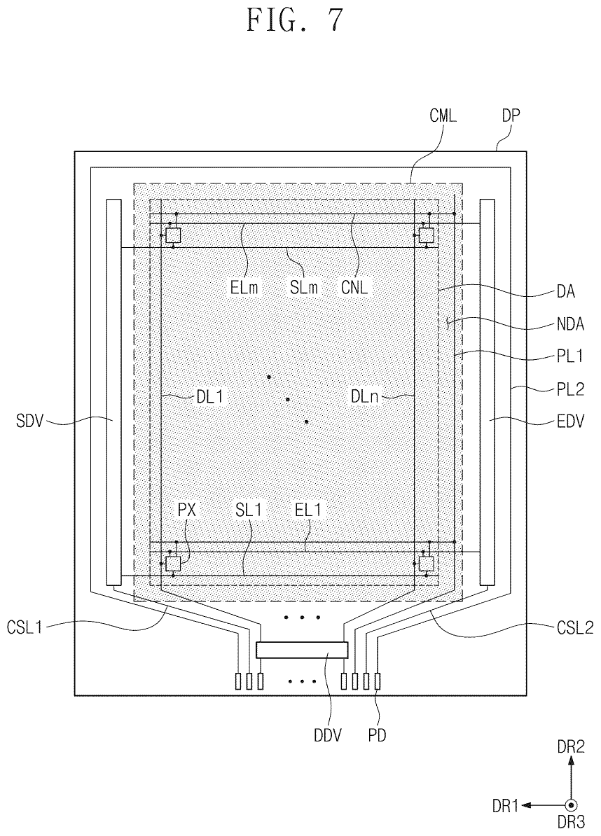

FIG. 7 is a plan view of a display panel that may be manufactured by using the mask assembly according to one or more embodiments of the present disclosure. For example, FIG. 7 illustrates a plan view of a display panel that may be manufactured by using the mask assembly illustrated in FIG. 1B.

Referring to FIG. 7, the display panel DP may have a rectangular shape having long sides extending in the second direction DR2 and short sides extending in the first direction DR1, but the shape of the display panel DP is not limited thereto. The display panel DP may include a display region DA and a non-display region NDA surrounding the display region DA. The display region DA may correspond to each of display regions DA of a mother substrate.

The display panel DP may be a light-emitting display panel. The display panel DP may be an organic light-emitting display panel or an inorganic light-emitting display panel. A light-emitting layer of the organic light-emitting display panel may contain an organic light-emitting material. A light-emitting layer of the inorganic light-emitting display panel may contain quantum dots, quantum rods, and the like. Hereinafter, the display panel DP will be described as an organic light-emitting display panel.

The display panel DP may include a plurality of pixels PX, a plurality of scan lines SL1 to SLm, a plurality of data lines DL1 to DLn, a plurality of light-emitting lines EL1 to ELm, first and second control lines CSL1 and CSL2, first and second power lines PL1 and PL2, connection lines CNL, and a plurality of pads PD, wherein m and n are natural numbers. Pixels PX may be fabricated on the display regions DA of the mother substrate described above.

The pixels PX may be located in the display region DA. A scan driver SDV and a light-emitting driver EDV may be located in the non-display region NDA adjacent to each of the long sides of the display panel DP. A data driver DDV may be located in the non-display region NDA adjacent to one of the short sides of the display panel DP. When viewed on a plane, the data driver DDV may be adjacent to a lower end of the display panel DP.

The scan lines SL1 to SLm may extend in the first direction DR1, and may be connected to the pixels PX and the scan driver SDV. The data lines DL1 to DLn may extend in the second direction DR2, and may be connected to the pixels PX and the data driver DDV. The light-emitting lines EL1 to ELm may extend in the first direction DR1, and may be connected to the pixels PX and the light-emitting driver EDV.

The first power line PL1 may extend in the second direction DR2, and may be located in the non-display region NDA. The first power line PL1 may be located between the display region DA and the light-emitting driver EDV, but without being limited thereto, the first power line PL1 may be located between the display region DA and the scan driver SDV.

The connection lines CNL may extend in the first direction DR1, and may be arranged in the second direction DR2. The connection lines CNL may be connected to the first power line PL1 and the pixels PX. A first voltage may be applied to the pixels PX through the first power line PL1 and the connection lines CNL connected to each other.

The second power line PL2 may be located in the non-display region NDA. The second power line PL2 may extend along the long sides of the display panel DP and the other short side of the display panel DP at which the data driver DDV is not located. The second power line PL2 may be located further outside than the scan driver SDV and the light-emitting driver EDV (e.g., further from the display area DA than the scan driver SDV and the light-emitting driver EDV).

In one or more embodiments, the second power line PL2 may extend toward the display region DA, and may be connected to the pixels PX. A second voltage having a lower level than the first voltage may be applied to the pixels PX through the second power line PL2.

The first control line CSL1 may be connected to the scan driver SDV, and may extend toward the lower end of the display panel DP when viewed on a plane. The second control line CSL2 may be connected to the light-emitting driver EDV, and may extend toward the lower end of the display panel DP when viewed on a plane. The data driver DDV may be located between the first control line CSL1 and the second control line CSL2.

The pads PD may be located on the display panel DP. The pads PD may be closer to the lower end/edge of the display panel DP than the data driver DDV. The data driver DDV, the first power line PL1, the second power line PL2, the first control line CSL1, and the second control line CSL2 may be connected to the pads PD. The data lines DL1 to DLn may be connected to the data driver DDV, and the data driver DDV may be connected to pads PD corresponding to the data lines DL1 to DLn.

In one or more embodiments, a timing controller for controlling the operation of the scan driver SDV, the data driver DDV, and the light-emitting driver EDV, and a voltage generator for generating first and second voltages may be located on a printed circuit board. The timing controller and the voltage generator may be connected to corresponding pads PD through the printed circuit board.

The scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DL1 to DLn. The light-emitting driver EDV may generate a plurality of light-emitting signals, and the light-emitting signals may be applied to the pixels PX through the light-emitting lines EL1 to ELm.

The pixels PX may receive data voltages in response to scan signals. The pixels PX may display an image by emitting light having a luminance corresponding to the data voltages in response to the light-emitting signals. The light-emitting time of the pixels PX may be controlled by the light-emitting signals.

The pixels PX may include a common layer CML. The pixels PX may share a common layer CML. The common layer CML may be located in the display region DA and in a portion of the non-display region NDA adjacent to the display region DA. For example, in FIG. 7, the common layer CML is illustrated as a gray dotted box. The common layer CML may not extend to the scan driver SDV, data driver DDV, and light-emitting driver EDV.

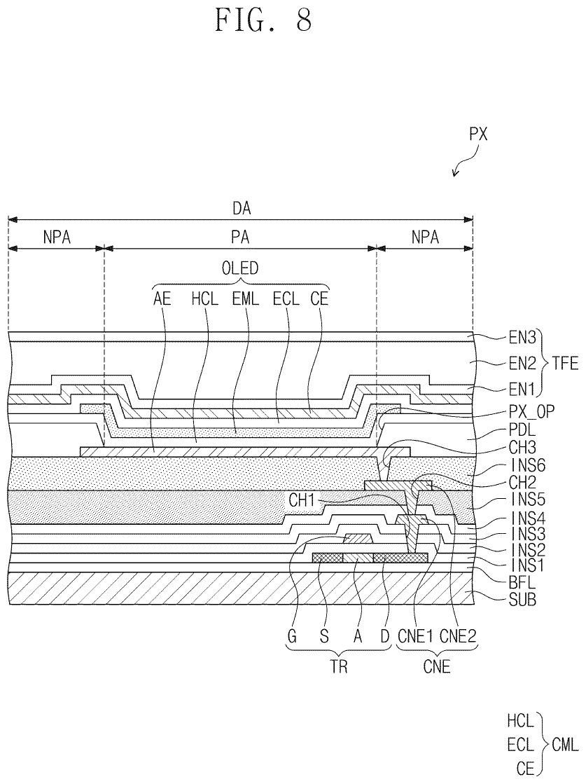

FIG. 8 illustrates a cross-sectional configuration of any one pixel illustrated in FIG. 7.

Referring to FIG. 8, each of the pixels PX illustrated in FIG. 7 may have the same structure as the pixel PX illustrated in FIG. 8. The pixel PX may be located on a substrate SUB, and may include a transistor TR and a light-emitting element OLED.

The light-emitting element OLED may be an organic light-emitting element. The light-emitting element OLED may include a first electrode AE, a second electrode CE, a hole control layer HCL, an electron control layer ECL, and a light-emitting layer EML. The first electrode AE may be an anode electrode, and the second electrode CE may be a cathode electrode. The aforementioned common layer CML may include a hole control layer HCL, an electron control layer ECL, and a second electrode CE.

The transistor TR and the light-emitting element OLED may be located on the substrate SUB. Although one transistor TR is illustrated as an example, the pixel PX may substantially include a plurality of transistors and at least one capacitor for driving the light-emitting element OLED.

The display region DA may include a light-emitting region PA corresponding to the pixel PX, and a non-light-emitting region NPA around the light-emitting region PA. The light-emitting element OLED may be located in the light-emitting region PA.

A buffer layer BFL may be located on the substrate SUB, and the buffer layer BFL may be an inorganic layer. A semiconductor pattern may be located on the buffer layer BFL. The semiconductor pattern may contain polysilicon. Without being limited thereto, however, the semiconductor pattern may contain amorphous silicon or metal oxide.

The semiconductor pattern may be doped with an N-type dopant or a P-type dopant. The semiconductor pattern may include a highly doped region and a lightly doped region. Conductivity of the highly doped region may be greater than that of the lightly doped region and substantially serve as a source electrode and a drain electrode of the transistor TR. The lightly doped region may substantially correspond to the active region (or channel) of the transistor.

A source S, an active region A, and a drain D of the transistor TR may be formed from the semiconductor pattern. A first insulating layer INS1 may be located on the semiconductor pattern. A gate G of the transistor TR may be located on the first insulating layer INS1. A second insulating layer INS2 may be located on the gate G. A third insulating layer INS3 may be located on the second insulating layer INS2.

A connection electrode CNE may be located between the transistor TR and the light-emitting element OLED, and may connect the transistor TR and the light-emitting element OLED to each other. The connection electrode CNE may include a first connection electrode CNE1 and a second connection electrode CNE2.

The first connection electrode CNE1 may be located on the third insulating layer INS3, and may be connected to the drain D through a first contact hole CH1 defined in the first to third insulating layers INS1 to INS3. A fourth insulating layer INS4 may be located on the first connection electrode CNE1. A fifth insulating layer INS5 may be located on the fourth insulating layer INS4.

The second connection electrode CNE2 may be located on the fifth insulating layer INS5. The second connection electrode CNE2 may be connected to the first connection electrode CNE1 through a second contact hole CH2 defined in the fourth insulating layer INS4 and the fifth insulating layer INS5. A sixth insulating layer INS6 may be located on the second connection electrode CNE2. The first to sixth insulating layers INS1, INS2, INS3, INS4, INS5, and INS6 may be inorganic layers or organic layers.

The first electrode AE may be located on the sixth insulating layer INS6. The first electrode AE may be connected to the second connection electrode CNE2 through a third contact hole CH3 defined in the sixth insulating layer INS6. A pixel defining film PDL exposing a portion (e.g., predetermined portion) of the first electrode AE may be located on the first electrode AE and the sixth insulating layer INS6. A pixel opening PX_OP exposing a portion (e.g., predetermined portion) of the first electrode AE may be defined in the pixel defining film PDL.

The hole control layer HCL may be located on the first electrode AE and the pixel defining film PDL. The hole control layer HCL may be located in common in the light-emitting region PA and the non-light-emitting region NPA. Accordingly, the hole control layer HCL may be defined as a common layer CML. The hole control layer HCL may include a hole transport layer and a hole injection layer.

The light-emitting layer EML may be located on the hole control layer HCL. The light-emitting layer EML may be located in a region corresponding to the pixel opening PX_OP. Accordingly, the light-emitting layer EML may overlap the light-emitting region PA. The light-emitting layer EML may contain an organic material. The light-emitting layer EML may generate any one of red, green, and blue light.

The electron control layer ECL may be located on the light-emitting layer EML and the hole control layer HCL. The electron control layer ECL may be commonly located in the light-emitting region PA and the non-light-emitting region NPA. Accordingly, the electron control layer ECL may be defined as a common layer CML. The electron control layer ECL may include an electron transport layer and/or an electron injection layer.

The second electrode CE may be located on the electron control layer ECL. The second electrode CE may be located in common in the light-emitting region PA and the non-light-emitting region NPA. Accordingly, the second electrode CE may be defined as a common layer CML.

A thin film encapsulation layer TFE may be located on the light-emitting element OLED. The thin film encapsulation layer TFE may be located on the second electrode CE to cover the pixel PX. The thin film encapsulation layer TFE may include a first thin film encapsulation layer EN1, a second thin film encapsulation layer EN2 located on the first thin film encapsulation layer EN1, and a third thin film encapsulation layer EN3 located on the second thin film encapsulation layer EN2.

The first and third thin film encapsulation layers EN1 and EN3 may include an inorganic layer, and the second thin film encapsulation layer EN2 may include an organic layer. The first and third thin film encapsulation layers EN1 and EN3 may protect the pixel PX from moisture/oxygen. The second thin film encapsulation layer EN2 may protect the pixel PX from foreign substances, such as dust particles.

A first voltage may be applied to the first electrode AE through the transistor TR, and a second voltage having a lower level than the first voltage may be applied to the second electrode CE. Holes and electrons injected into the light-emitting layer EML may be combined with each other to form excitons, and the light-emitting element OLED may emit light while the excitons transition to a ground state.

In one or more embodiments of the present disclosure, the aforementioned mask assembly MSA (see FIG. 6B) may be used to form the hole control layer HCL, the electron control layer ECL, and/or the second electrode CE of the common layer CML. The hole control layer HCL, the electron control layer ECL, and the second electrode CE may be sequentially formed on the substrate SUB.

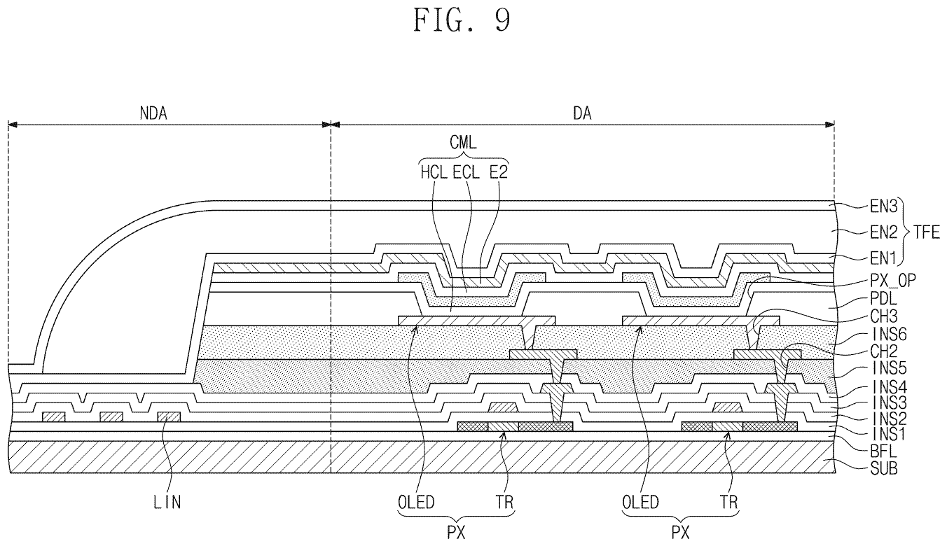

FIG. 9 illustrates a cross section of the display panel adjacent to an edge of a display region in FIG. 7.

Referring to FIGS. 8 and 9, like the display panel DP, the substrate SUB may include a display region DA, and a non-display region NDA around the display region DA. Pixels PX may be located on the display region DA of the substrate SUB.

The buffer layer BFL and the first to fourth insulating layers INS1 to INS4 may be located on the display region DA and the non-display region NDA. The fifth and sixth insulating layers INS5 and INS6 and the pixel defining film PDL may be located on the display region DA, and on a portion of the non-display region NDA adjacent to the display region DA.

The first and third thin film encapsulation layers EN1 and EN3 may be located on the display region DA and the non-display region NDA. The first thin film encapsulation layer EN1 may be located on the pixels PX. On the non-display region NDA, the first thin film encapsulation layer EN1 may cover edges of the fifth and sixth insulating layers INS5 and INS6 and the pixel defining film PDL, and may be located on the fourth insulating layer INS4.

The second thin film encapsulation layer EN2 may be located on the display region DA, and on a portion of the non-display region NDA adjacent to the display region DA. On the non-display region NDA, the second thin film encapsulation layer EN2 may cover an edge of the first thin film encapsulation layer EN1. On the non-display region NDA, the third thin film encapsulation layer EN3 may cover an edge of the second thin film encapsulation layer EN2.

A plurality of lines LIN may be located on the non-display region NDA. The lines LIN may include various lines, such as data lines DL1 to DLn, light-emitting lines EL1 to ELm, and first and second control lines CSL1 and CSL2 extending to the non-display region NDA.

The hole control layer HCL, the electron control layer ECL, and the second electrode CE may be commonly located in the pixels PX. That is, the common layer CML may be commonly located in the pixels PX. The common layer CML may be located on the display region DA, and may extend onto a portion of the non-display region NDA adjacent to the display region DA. On the non-display region NDA, the common layer CML may be located on the pixel defining film PDL.

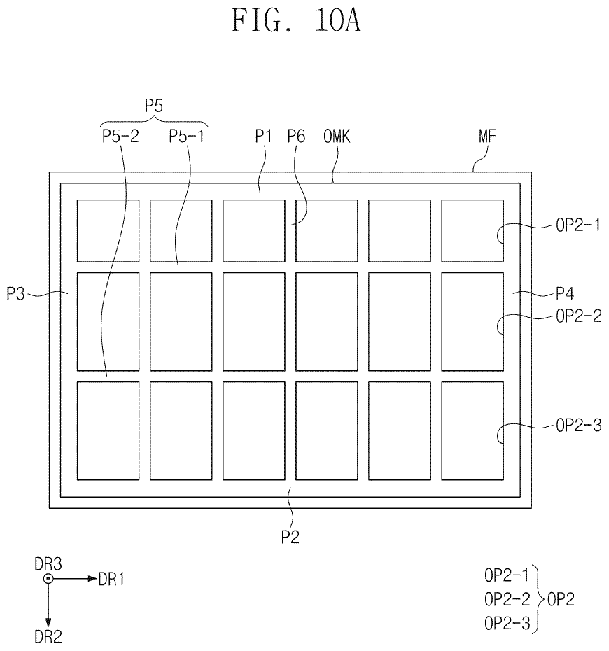

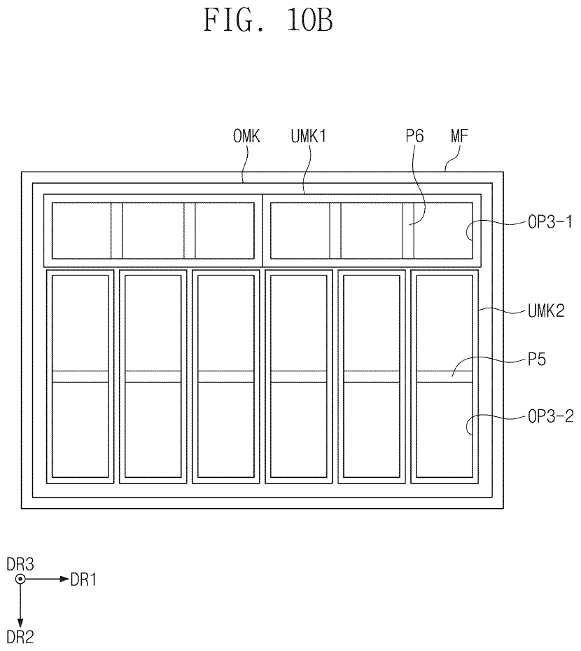

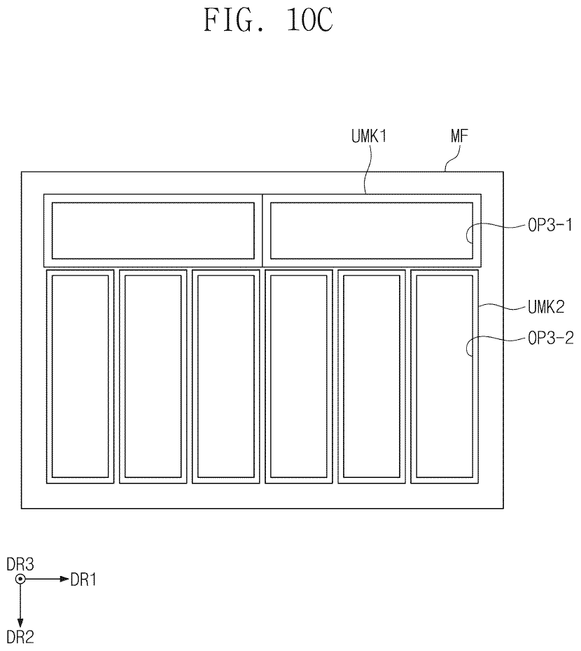

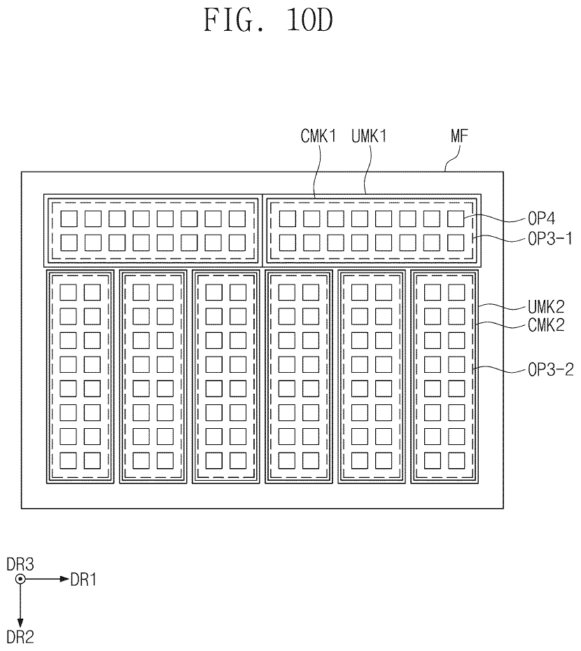

FIGS. 10A to 10D schematically illustrate a method of manufacturing a mask assembly according to one or more embodiments of the present disclosure. FIGS. 10A to 10D schematically show drawings for explaining a manufacturing process of the mask assembly MSA illustrated in FIGS. 1A and 1B. Same/similar reference numerals will be used for the same/similar components as those described in FIGS. 1A to 9, and redundant descriptions will be omitted. The method of manufacturing the mask assembly according to one or more embodiments of the present disclosure may include coupling an open mask onto a mask frame, coupling unit masks onto the open mask, and coupling cell masks onto the unit masks.

FIG. 10A is a plan view illustrating a state in which the mask frame MF and the open mask OMK illustrated in FIG. 1A are coupled to each other.

Referring to FIGS. 1B and 10A, the mask frame MF and the open mask OMK may be prepared, and the open mask OMK may be located on the top surface of the mask frame MF. The open mask OMK may be coupled to the top surface of the mask frame MF. For example, the open mask OMK may be coupled to the top surface of the mask frame MF by laser welding. The second outer side surface OS2 of the open mask OMK may be spaced apart from the first outer side surface OS1 of the mask frame MF. That is, the edge of the open mask OMK may be located further inside than the edge of the mask frame MF.

Referring to FIGS. 1A, 2A, 5, and 10A together, on a plane, the second outer side surface OS2 of the open mask OMK may be located between the first outer side surface OS1 and the first inner side surface IS1 of the mask frame MF (e.g., in plan view). When viewed on a plane, a portion of the open mask OMK adjacent to the second outer side surface OS2 of the open mask OMK may overlap the mask frame MF.

When viewed on a plane, the second openings OP2 of the open mask OMK may overlap, and may be located in, the first opening OP1. On a plane, the second openings OP2 may be located further inside than the first inner side surface IS1, and may not overlap the mask frame MF.

As described above, the open mask OMK may include the first to sixth portions P1, P2, P3, P4, P5, and P6, and in a state in which the cell masks CMK are not coupled onto the open mask OMK, the open mask OMK may include the (2-1)-th openings OP2-1, the (2-2)-th openings OP2-2, and the (2-3)-th openings OP2-3 defined by the first to sixth portion P1, P2, P3, P4, P5, and P6. That is, because the second openings OP2 in the coupling of the unit masks UMK include the (2-1)-th openings OP2-1, the (2-2)-th openings OP2-2, and the (2-3)-th openings OP2-3, the second openings OP2 in the coupling of the unit masks UMK may be greater in number than the second openings OP2 including the (2-4)-th and (2-5)-th openings OP2-4 and OP2-5 (see FIG. 1B) in the coupling of the cell masks CMK to be described later, and may be smaller in size on a plane. The fifth portion P5 and the sixth portion P6 may be provided in plurality. For example, the (5-1)-th portion P5-1 may be provided between the (2-1)-th openings OP2-1 and the (2-2)-th openings OP2-2, and the (5-2)-th portion P5-2 may be provided between the (2-2)-th openings OP2-2 and the (2-3)-th openings OP2-3. In addition, each of the sixth portions P6 may be provided between adjacent (2-1)-th openings OP2-1, between adjacent (2-2)-th openings OP2-2, and between adjacent (2-3)-th openings OP2-3.

With regard to the (2-1)-th openings OP2-1, the (2-2)-th openings OP2-2, and the (2-3)-th openings OP2-3, in an operation to be described later, at least a portion of the fifth portion P5 and at least a portion of the sixth portion P6 may be removed so that three (2-1)-th openings OP2-1 may form an integral opening, and one (2-2)-th opening OP2-2 and one (2-3)-th opening OP2-3 may form an integral opening.

FIG. 10B is a plan view illustrating a state in which the mask frame MF, the open mask OMK, and the unit masks UMK illustrated in FIG. 1A are coupled to each other.

Referring to FIGS. 1A, 3, and 10B, the unit masks UMK are prepared, and the unit masks UMK may be located on the top surface of the open mask OMK. Each of the unit masks UMK may be located on a plurality of second openings OP2.

For example, each of the first unit masks UMK1 may overlap a plurality of (2-1)-th openings OP2-1. On a plane, each of the first unit masks UMK1 may overlap three (2-1)-th openings OP2-1. Accordingly, when viewed on a plane, three (2-1)-th openings OP2-1 divided by the sixth portions P6 may be recognized from the outside through the first unit opening OP3-1 of each of the first unit masks UMK1.

For example, each of the second unit masks UMK2 may overlap corresponding ones of the (2-2)-th and (2-3)-th openings OP2-2 and OP2-3. On a plane, each of the second unit masks UMK2 may overlap one (2-2)-th opening OP2-2 and one (2-3)-th opening OP2-3. Accordingly, when viewed on a plane, the (2-2)-th opening OP2-2 and the (2-3)-th opening OP2-3 divided by the fifth portion P5 may be recognized from the outside through the second unit opening OP3-2 of each of the second unit masks UMK2.

The unit masks UMK may be coupled directly to the open mask OMK without being stretched. Because the unit masks UMK are smaller in size than the open mask OMK, and are less likely to sag due to support by the first to sixth portions P1 to P6, the unit masks UMK may be coupled to the open mask OMK without a separate stretching process. Without being limited thereto, however, the unit masks UMK may also be stretched and then coupled to the open mask OMK.

FIG. 10C is a plan view illustrating a state in which a portion of the open mask OMK is removed after the mask frame MF, the open mask OMK, and the unit masks UMK (illustrated in FIG. 1A) have been coupled to each other. The open mask OMK illustrated in FIG. 10C may correspond to the open mask OMK illustrated in FIGS. 1B and 2B.

Referring to FIGS. 1B, 2A, 2B, 10B, and 10C, at least a portion of the open mask OMK may be removed in a state in which the unit masks UMK are coupled to the top surface of the open mask OMK.

For example, it is possible to remove a portion of the open mask OMK recognized from the outside through the first unit opening OP3-1 of the first unit mask UMK1 and the second unit opening OP3-2 of the second unit mask UMK2. For example, on a plane, the fifth portions P5 overlapping the first unit opening OP3-1 may be removed, and the sixth portions P6 overlapping the second unit opening OP3-2 may be removed. Accordingly, each of the second openings OP2 of the open mask OMK may correspond to each of the first and second unit openings OP3-1 and OP3-2. The fifth portions P5 and the sixth portions P6 to be removed from the open mask OMK may be removed by using laser, but the present disclosure is not limited thereto.

FIG. 10D illustrates a state in which the mask frame, the open mask, the unit masks, and the cell masks illustrated in FIG. 1B are coupled to each other. Compared to FIG. 1B, FIG. 10D illustrates a structure in which a plurality of cell openings are defined in each of the cell masks.

Referring to FIGS. 1B, 10C, and 10D, the cell masks CMK1 and CMK2 are prepared, and the cell masks CMK1 and CMK2 may be located on the top surfaces of the unit masks UMK1 and UMK2. The cell masks CMK1 and CMK2 may be respectively located on the unit openings OP3-1 and OP3-2.

According to one or more embodiments of the present disclosure, the cell masks CMK1 and CMK2 may be located on the unit masks UMK1 and UMK2 after the fifth portions P5 and the sixth portions P6 of the open mask OMK overlapping the unit openings OP3-1 and OP3-2 on a plane have been removed. On a plane, the first cell masks CMK1 may respectively overlap the first unit openings OP3-1. On a plane, the cell openings OP4 of the first cell masks CMK1 may respectively overlap the first unit openings OP3-1.

In addition, on a plane, the second cell masks CMK2 may respectively overlap the second unit openings OP3-2. On a plane, the cell openings OP4 of the second cell masks CMK2 may respectively overlap the second unit openings OP3-2.

As described above, before the cell masks CMK1 and CMK2 are coupled onto the unit masks UMK1 and UMK2, the fifth portions P5 and the sixth portions P6 of the open mask OMK overlapping the unit openings OP3-1 and OP3-2 are removed, and therefore, on a plane, each of the cell openings OP4 may not overlap the fifth portions P5 and the sixth portions P6 of the open mask OMK.

The cell masks CMK1 and CMK2 may be coupled to the top surfaces of the unit masks UMK1 and UMK2 by welding. Portions of the cell masks CMK1 and CMK2 adjacent to the outer side surfaces of the cell masks CMK1 and CMK2 may be coupled to the unit masks UMK1 and UMK2 by welding. Without being limited thereto, however, the portions of the cell masks CMK1 and CMK2 adjacent to the outer side surfaces of the cell masks CMK1 and CMK2 may be respectively attached to the unit masks UMK1 and UMK2 by an adhesive.

The cell masks CMK1 and CMK2 may be coupled directly to the unit masks UMK1 and UMK2 without being stretched. Because the cell masks CMK1 and CMK2 having a smaller size than the open mask OMK are less likely to sag, they may be coupled to the open mask OMK without a separate stretching process. Without being limited thereto, however, the cell masks CMK1 and CMK2 may also be stretched and then coupled to the open mask OMK.

The cell masks CMK1 and CMK2 may be spaced apart from the outer side surfaces of the unit masks UMK1 and UMK2. That is, the cell masks CMK1 and CMK2 may be located further inside than the edges of the unit masks UMK1 and UMK2 (e.g., in plan view).

When viewed on a plane, the cell masks CMK1 and CMK2 may overlap the unit openings OP3-1 and OP3-2. On a plane, the cell masks CMK1 and CMK2 may be located in the unit openings OP3-1 and OP3-2.

On a plane, the cell openings OP4 of the cell masks CMK1 and CMK2 may have smaller areas than the unit openings OP3-1 and OP3-2. The cell openings OP4 may respectively overlap the unit openings OP3-1 and OP3-2 and may be located in the unit openings OP3-1 and OP3-2.

According to one or more embodiments of the present disclosure, the mask assembly may prevent sagging due to the weight of a mask sheet itself even when one mask sheet is formed from a plurality of masks.

For example, in the mask assembly according to one or more embodiments of the present disclosure, phenomena, such as sagging and distortion of the mask assembly, may be suppressed from occurring when the cell masks respectively correspond to openings on the open mask in which the openings having different shapes are defined. Accordingly, when the mask assembly according to this present disclosure is used, it is possible to suppress the occurrence of defects during deposition of a common layer.

In addition, by using a plurality of mask assemblies manufactured by the method of manufacturing the mask assembly according to one or more embodiments of the present disclosure, it is possible to increase the number of display panels that may be manufactured from a mother glass, thereby reducing costs.

Although the above has been described with reference to preferred embodiments of the present disclosure, those skilled in the art or those of ordinary skill in the art will understand that various modifications and changes can be made to the present disclosure within the scope that does not depart from the spirit and technical field of the present disclosure described in the claims. Accordingly, the technical scope of the present disclosure should not be limited to the content described in the detailed description of the specification, but should be determined by the claims described hereinafter, with functional equivalents thereof to be included therein.

What is claimed is:

1. A mask assembly comprising:
a mask frame defining a first opening;
an open mask above the mask frame, and defining second openings arranged in a first direction and a second direction crossing the first direction;
unit masks above the open mask, and defining a unit opening, the unit opening having an area that is less than an area of each of the second openings in plan view; and
cell masks above the unit masks, and defining cell openings, one of the cell openings have an area that is less than the area of the unit opening.

2. The mask assembly of claim 1, wherein the unit masks comprise a first unit mask defining a first unit opening, and a second unit mask defining a second unit opening,
wherein the first unit mask comprises:
two first long side portions extending in the first direction, and spaced apart in the second direction; and
two first short side portions extending in the second direction, and spaced apart in the first direction, the two first short side portions and the two first long side portions being connected to define the first unit opening,
wherein the second unit mask comprises:
two second short side portions extending in the first direction, and spaced apart in the second direction; and
two second long side portions extending in the second direction, and spaced apart in the first direction, the two second short side portions and the two second long side portions being connected to define the second unit opening.

3. The mask assembly of claim 2, wherein an area of the first unit opening is substantially equal to an area of the second unit opening in plan view.

4. The mask assembly of claim 2, wherein the first short side portions and the first long side portions have a same first width in plan view, and
wherein the second short side portions and the second long side portions have a same second width in plan view, the second width being less than the first width.

5. The mask assembly of claim 2, wherein the first unit mask and the second unit mask are provided in plurality in the first direction, and
wherein the second unit mask is spaced apart from the first unit mask in the second direction.

6. The mask assembly of claim 2, wherein a length of the first long side portions is greater than a length of the second long side portions.

7. The mask assembly of claim 2, wherein a length of the first short side portions is greater than a length of the second short side portions.

8. The mask assembly of claim 2, wherein a first thickness of the first unit mask is greater than a second thickness of the second unit mask.

9. The mask assembly of claim 8, wherein the first thickness is about 100 μm to about 150 μm.

10. The mask assembly of claim 1, wherein the open mask and the unit masks comprise a same material.

11. The mask assembly of claim 10, wherein the open mask and the unit masks comprise stainless steel or an INVAR® alloy.

12. A mask assembly comprising:
a mask frame defining a first opening;
an open mask above the mask frame, and defining second openings arranged in a first direction and in a second direction crossing the first direction;
unit masks above the open mask, and defining a unit openings respectively corresponding to the second openings; and
a cell mask above the unit masks, and defining cell openings respectively corresponding to the unit openings.

13. The mask assembly of claim 12, wherein the unit openings have a smaller area than the second openings corresponding thereto, in plan view.

14. The mask assembly of claim 12, wherein the unit masks comprise a first unit mask defining a first unit opening, and a second unit mask defining a second unit opening,
wherein the first and second unit masks are provided in plurality in the first direction, and are spaced apart in the second direction,
wherein a width of the first unit opening in the first direction is greater than a width of the second unit opening in the first direction; and
wherein a width of the first unit opening in the second direction is less than a width of the second unit opening in the second direction.

15. The mask assembly of claim 14, wherein the first unit mask is provided in two, and the second unit mask is provided in six.

16. A method for manufacturing a mask assembly, the method comprising:
preparing a mask frame defining a first opening;
coupling, to a top surface of the mask frame, an open mask defining second openings in a first direction and a second direction crossing the first direction;
coupling, to a top surface of the open mask, unit masks defining unit openings respectively corresponding to two or more of the second openings; and
coupling, to top surfaces of the unit masks, cell masks defining cell openings,
wherein a number of the second openings decreases between the coupling of the unit masks and the coupling of the cell masks, and
wherein, in plan view, a size of the second openings increases between the coupling of the unit masks and the coupling of the cell masks.

17. The method of claim 16, wherein the unit masks comprise a first unit mask defining a first unit opening, and a second unit mask defining a second unit opening,
wherein the first unit mask and the second unit mask are spaced apart in the second direction,
wherein a width of the first unit opening in the first direction is greater than a width of the second unit opening in the first direction, and
wherein a width of the first unit opening in the second direction is less than a width of the second unit opening in the second direction.

18. The method of claim 17, wherein a first thickness of the first unit mask is greater than a second thickness of the second unit mask.

19. The method of claim 16, wherein the open mask comprises:
a first portion and a second portion spaced apart in the second direction and extending in the first direction;
a third portion connecting one end of the first portion to one end of the second portion;
a fourth portion connect another end of the first portion to another end of the second portion;
fifth portions spaced apart in the second direction between the first portion and the second portion; and
sixth portions spaced apart in the first direction between the third portion and the fourth portion, and
wherein the method further comprises, prior to coupling the cell masks, removing the fifth and sixth portions overlapping the unit opening in plan view.

20. The method of claim 16, wherein the cell openings are provided in plurality in each of the cell masks; and
wherein the cell openings defined in each of the cell masks are in the unit openings corresponding thereto in plan view.
